(19) United States
(12) Patent Application Publication
(10) Pub. No.: US 2013/0089972 A1
(43) Pub. Date: Apr. 11, 2013

(54) METHOD FOR FORMING NANOCRYSTALLINE SILICON FILM

(71) Applicants: Min Koo Han, Seoul (KR); Sun Jae Kim, Seoul (KR)

(72) Inventors: Min Koo Han, Seoul (KR); Sun Jae Kim, Seoul (KR)

(73) Assignee: SNU R&DB FOUNDATION, Seoul (KR)

(21) Appl. No.: 13/253,616

(22) Filed: Oct. 5, 2011

(51) Int. Cl. H01L 21/20

(52) U.S. Cl. 438/478; 257/E21.09

(57) ABSTRACT

Provided is a method for forming a nanocrystalline silicon film that can be deposited on a substrate while maintaining a high degree of crystallinity at low temperatures. The method includes performing plasma treatment on a substrate, and forming a nanocrystalline silicon film by depositing the nanocrystalline silicon film on the substrate.

### BACKGROUND OF THE INVENTION

1. Field of the Invention

The present invention relates generally to a method for forming a nanocrystalline silicon film.

2. Description of the Related Art

A flexible display is a bendable display. The flexible display is formed by mounting an active matrix organic light emitting diode (AMOLED) using a thin film transistor (TFT), or an active matrix liquid crystal display (AMLCD) on a flexible substrate. Since the flexible display employs a plastic substrate, instead of a generally used glass substrate, a low temperature process is required in the manufacture of the flexible display to prevent the substrate from being damaged due to heat.

Specifically, the thin film transistor is formed such that a silicon oxide layer is first on a flexible substrate, and a semiconductor layer, a gate electrode, a source electrode and a drain electrode are then stacked to form a channel region. In particular, the semiconductor layer may be formed of one of amorphous silicon, polycrystalline silicon and nanocrystalline silicon. Specifically, the semiconductor layer based on polycrystalline silicon is formed by depositing amorphous silicon, followed by annealing. The semiconductor layer based on nanocrystalline silicon may be formed without annealing, thereby simplifying the process while demonstrating excellent uniformity. In addition, the semiconductor layer based on nanocrystalline silicon is better than the semiconductor layer based on amorphous silicon in view of electrical characteristic and reliability. Therefore, in recent years, a nanocrystalline silicon thin film transistor has been widely used as a display driving device. Accordingly, there is a need for improving the electrical characteristic of the nanocrystalline silicon deposited on the thin film transistor.

### SUMMARY OF THE INVENTION

Embodiments of the present invention provide a method for forming a nanocrystalline silicon film that can be deposited on a substrate while maintaining a high degree of crystallinity at low temperatures.

According to an embodiment of the present invention, a method for forming a nanocrystalline silicon film, the method including performing plasma treatment on a substrate, and forming a nanocrystalline silicon film by depositing the nanocrystalline silicon film on the substrate.

Here, the forming of the nanocrystalline silicon film may include depositing the nanocrystalline silicon film by inductively coupled plasma-chemical vapor deposition (ICP-CVD).

The plasma treatment may be helium (He) plasma treatment or hydrogen (H₂) plasma treatment.

The performing of the plasma treatment may perform the plasma treatment until the substrate surface reaches a temperature in a range of 80° C. to 150° C.

The ICP-CVD may be performed using SiH4 or diluted helium (He) as a reactant gas.

In the forming of the nanocrystalline silicon film, a chamber deposition pressure may range from 30 mT to 250 mT.

In addition, the forming of the nanocrystalline silicon film, the chamber deposition pressure may be 50 mT.

ICP power intensity of the ICP-CVD may range from 600 W to 800 W.

In addition, the ICP power intensity of the ICP-CVD may be 700 W.

As described above, the method for forming a nanocrystalline silicon film according to the present invention allows the nanocrystalline silicon film to be formed at a low temperature (approximately 200° C. or less) without externally heating a substrate. Therefore, the method for forming a nanocrystalline silicon film according to the present invention is advantageous in forming a nanocrystalline silicon film on a flexible substrate that is weak at heat.

In addition, in the method for forming a nanocrystalline silicon film according to the present invention, it is possible to form a nanocrystalline silicon film having a thin incubation layer while having a high degree of crystallinity.

Additional aspects and/or advantages of the invention will be set forth in part in the description which follows and, in part, will be obvious from the description, or may be learned by practice of the invention.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 is a flow chart illustrating a method for forming a nanocrystalline silicon film according to the present invention;

FIG. 2 is a graph illustrating changes in the surface temperature of a substrate when helium (He) plasma and hydrogen (H₂) plasma treatment are performed on the substrate;

FIG. 3 is a graph illustrating changes in the temperature of a substrate when a nanocrystalline silicon film is deposited after plasma treatment and after externally heating;

FIGS. 4A to 4C are a scanning electron microscope (SEM) photograph, a Raman shift analysis and a transmission electron microscope (TEM) photograph of a silicon film deposited by Example 2;

FIGS. 5A to 5C are an SEM photograph, a Raman shift analysis and a TEM photograph of a silicon film deposited by Example 3;

FIG. 6 is an SEM photograph of a silicon film deposited by Comparative Example 2;

FIG. 7A to 7C are an SEM photograph, a Raman spectroscopic analysis and a TEM photograph of a silicon film deposited by Comparative Example 3;

FIG. 8 is a graph illustrating a Raman spectroscopic analysis of a silicon film deposited by Comparative Example 4;

FIG. 9 is an SEM photograph of a silicon film deposited by Comparative Example 5;

FIGS. 10A to 10C are an SEM photograph, a Raman spectroscopic analysis and a TEM photograph of a silicon film deposited by Comparative Example 6;

FIG. 11 is a graph illustrating a Raman spectroscopic analysis of a silicon film deposited by Comparative Example 7;

FIG. 12 is an SEM photograph of a silicon film deposited by Comparative Example 8;

FIG. 13 is an SEM photograph of a silicon film deposited by Comparative Example 9;

FIG. 14 is an SEM photograph of a silicon film deposited by Comparative Example 10;

FIG. 15 is a graph illustrating a Raman spectroscopic analysis of silicon films deposited by Example 1 and Example 3; and

FIG. 16 is a graph illustrating a Raman spectroscopic analysis of silicon films deposited by Example 2 and Example 4.

In the following description, the same or similar elements are labeled with the same or similar reference numbers.

### DETAILED DESCRIPTION

The present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Preferred embodiments will now be described more fully hereinafter with reference to the accompanying drawings. However, they may be embodied in different forms and should not be construed as limited to the embodiments set forth herein. Rather, these embodiments are provided so that this disclosure will be thorough and complete, and will fully convey the scope of the disclosure to those skilled in the art.

Hereinafter, a method for forming a nanocrystalline silicon film will be described with reference to the accompanying drawings.

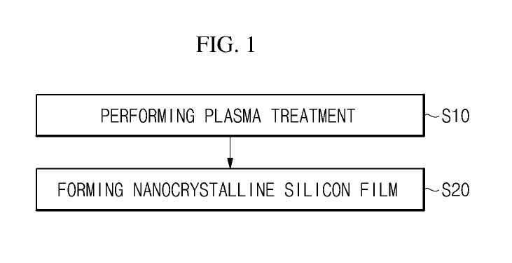

FIG. 1 is a flow chart illustrating a method for forming a nanocrystalline silicon film according to the present invention.

Referring to FIG. 1, the method for forming a nanocrystalline silicon film according to the present invention may include performing plasma treatment (S10) and forming a nanocrystalline silicon film (S20).

In the performing of plasma treatment (S10), plasma treatment is performed on a substrate where a nanocrystalline silicon film is to be deposited. The plasma treatment may be helium (He) plasma treatment or hydrogen (H₂) plasma treatment. Further, the plasma treatment may be done by helium (He) plasma treatment and hydrogen (H₂) plasma treatment simultaneously. The substrate may be any substrate used in forming a thin film transistor. In the plasma treatment, heat energy for decomposing the reactant gas in the forming of a nanocrystalline silicon film, which will later be described, is supplied to the substrate.

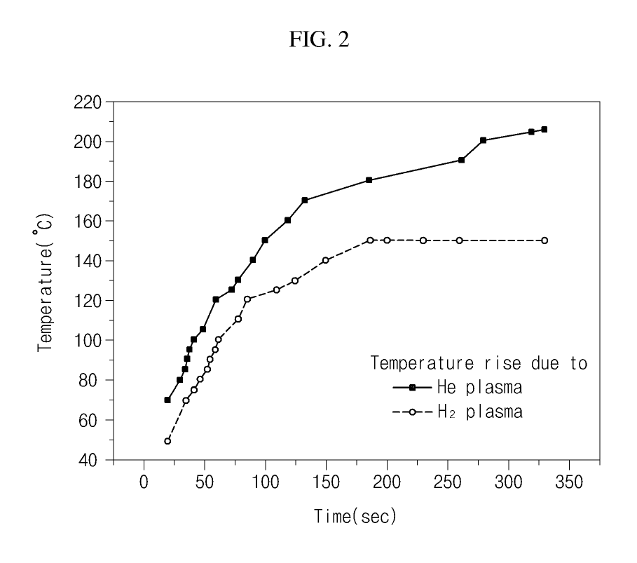

FIG. 2 is a graph illustrating changes in the surface temperature of a substrate when helium (He) plasma treatment and hydrogen (H₂) plasma treatment are performed on the substrate. In FIG. 2, the abscissa indicates time (sec) and the ordinate indicates substrate surface temperature (°C). The upper graph indicated by solid line illustrates time-to-temperature change of a substrate surface when He plasma treatment is performed on a silicon substrate. In addition, the lower graph indicated by dotted line illustrates time-to-temperature change of a substrate surface when H₂ plasma treatment is performed on a silicon substrate. In addition, the experiments shown in FIG. 2 were carried out on 1000 Å thick silicon substrates under process conditions including the He or H₂ gas flow rate of 50 sccm (standard cubic centimeters per minute), RF power intensity of 700 W, and chamber pressure of 50 mT. As confirmed from the graphs shown in FIG. 2, the silicon substrate surface temperature rises over time. In detail, the temperature of the substrate with He plasma treatment performed thereon rises to approximately 100° C. after 40 seconds elapsed, and to approximately 200° C. after 300 seconds elapsed. In addition, the temperature of the substrate with H₂ plasma treatment performed thereon rises to approximately 70° C. after 40 seconds elapsed, and to approximately 140° C. after 300 seconds elapsed. Accordingly, sufficient heat energy may be supplied to the silicon substrate only with plasma treatment. Preferably, the plasma treatment is continuously performed until the temperature of the substrate reaches a temperature ranging from 80° C. to 150° C. When the temperature of the substrate is less than 80° C., in the forming of a nanocrystalline silicon film (S20), which will later be described, the substrate may not have sufficient heat energy for decomposing the reactant gas during chemical vapor deposition (CVD) performed on the substrate. When the temperature of the substrate is greater than 150° C., the temperature of the substrate exceeds 200° C. during CVD in the forming of a nanocrystalline silicon film (S20), damages to a substrate, particularly a flexible plastic substrate that is weak at heat, may be caused.

In the forming of a nanocrystalline silicon film (S20), the nanocrystalline silicon film is deposited on the substrate. In particular, the nanocrystalline silicon film may be deposited on the substrate with plasma treatment performed thereon. The depositing of the nanocrystalline silicon film may be performed by one of inductively coupled plasma-chemical vapor deposition (ICP-CVD, plasma enhanced chemical vapor deposition (PECVD) and electron cyclotron resonance chemical vapor deposition (ECR-CVD). However, the present invention is not limited to the above mentioned deposition methods. Specifically, the ICP-CVD activates gas decomposition even at low temperatures by generating high density plasma. In addition, in the ICP-CVD, since remote plasma is used, a distance between a plasma generation zone and a substrate is large, so that damages of plasma based film-growth zone due to ions can be suppressed. The forming of a nanocrystalline silicon film (S20) may be performed using SiH4₄ or diluted He as a reactant gas. In an alternative embodiment, the forming of a nanocrystalline silicon film (S20) may be performed using the mixture of SiH4₄ and diluted He as a reactant gas. However, other types of reactant gas may be used without departing from the spirit and scope of the present invention.

Preferably, in the forming of a nanocrystalline silicon film (S20), a chamber deposition pressure in the ICP-CVD may range from 30 mT to 250 mT. More preferably, a chamber deposition pressure in the ICP-CVD may be 50 mT. Ions and electrons have high energy within the above-described range of the chamber deposition pressure, thereby facilitating decomposition of the reactant gas into radicals. On the other hand, if the chamber deposition pressure is less than 30 mT, it is difficult to uniformly deposit a nanocrystalline silicon film. In addition, if the chamber deposition pressure exceeds 250 mT, stable deposition of the nanocrystalline silicon film is difficult to achieve due to collision of activated ions and radicals, thereby lowering the deposition efficiency.

In addition, the ICP power intensity of ICP-CVD is preferably in a range of 600 W to 800 W, more preferably 700 W. A nanocrystalline silicon film having a clear steric grain structure can be deposited within the above-stated range of ICP power intensity. If ICP power intensity is less than 600 W or greater than 800 W, the deposited silicon film may not be crystalline but may be amorphous.

A more detailed explanation of the present invention is given below based on Comparative Examples and Examples illustrating changes in the substrate surface temperature demonstrated during deposition of nanocrystalline silicon films with or without plasma treatment performed on the substrate.

### EXAMPLE 1

A 1000 Å thick silicon substrate was prepared and He plasma treatment was performed on the silicon substrate until the silicon substrate reached a temperature of 150° C. A nanocrystalline silicon film was deposited on the silicon substrate to a thickness of 1000 Å by ICP-CVD under process conditions including RF power of 700 W, reactant gas (He:SiH₄) composition ratio He:SiH₄=40:3 [sccm], and chamber pressure of 50 mT.

### COMPARATIVE EXAMPLE 1

A 1000 Å thick silicon substrate was prepared and then externally heated until the silicon substrate reached a temperature of 150° C. A nanocrystalline silicon film was deposited on the silicon substrate to a thickness of 1000 Å by ICP-CVD under process conditions including RF power of 700 W, reactant gas (He:SiH₄) composition ratio He:SiH₄=40:3 [sccm], and chamber pressure of 50 mT.

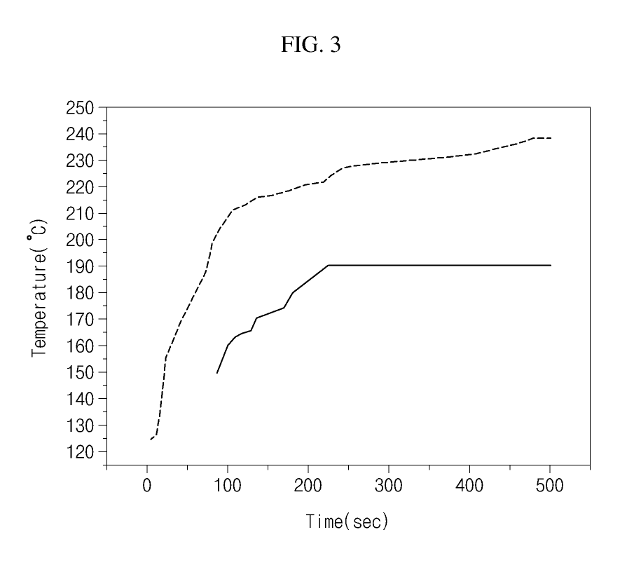

FIG. 3 is a graph illustrating changes in the temperature of a substrate when a nanocrystalline silicon film is deposited after plasma treatment (Example 1) and after externally heating (Comparative Example 1). In FIG. 3, the abscissa indicates time (sec) and the ordinate indicates substrate surface temperature (°C). The graph indicated by solid line illustrates time-to-temperature change of a substrate surface in Example 1, and the graph indicated by dotted line illustrates time-to-temperature change of a substrate surface in Comparative Example 1. As confirmed from the graphs shown in FIG. 3, the silicon substrate surface temperature rises over time. In detail, the temperature of the substrate of Comparative Example 1 rises to approximately 240° C. and the temperature of the substrate of Example 1 rises to approximately 190° C., to then demonstrate a flattened temperature distribution. A plastic substrate used for a flexible display should be processed at a temperature of lower than approximately 200° C. to avoid defects of the substrate. Therefore, compared to Comparative Example 1 in which the substrate was externally heated and a nanocrystalline silicon film was then deposited, in Example 1 in which the substrate was subjected to plasma treatment and a nanocrystalline silicon film was then deposited, the nanocrystalline silicon film could be formed at a temperature low enough to prevent the substrate from being damaged.

Hereinafter, in forming nanocrystalline silicon films according to Comparative Examples and Examples, it is determined whether the nanocrystalline silicon films deposited while varying chamber deposition pressure and ICP power intensity are crystalline or amorphous, and degrees of crystallinity of crystalline films are obtained in the following manners.

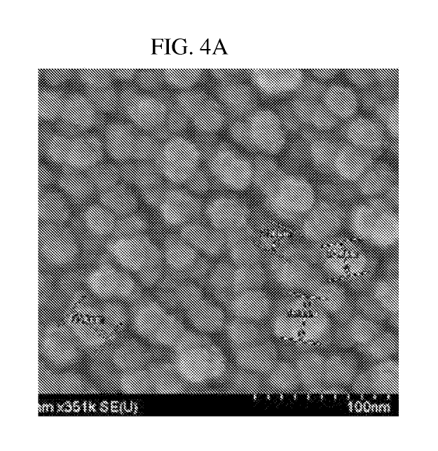

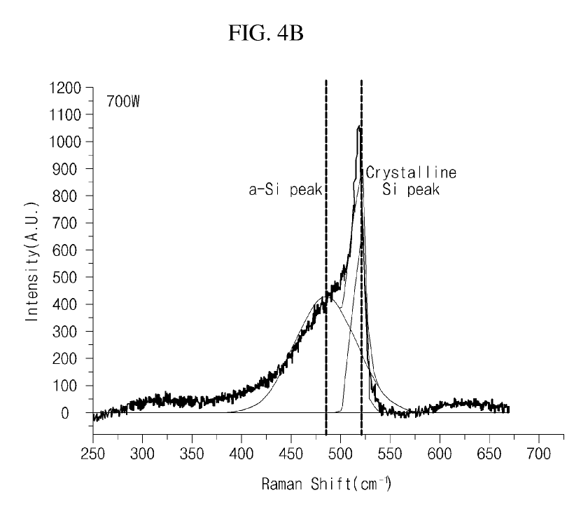

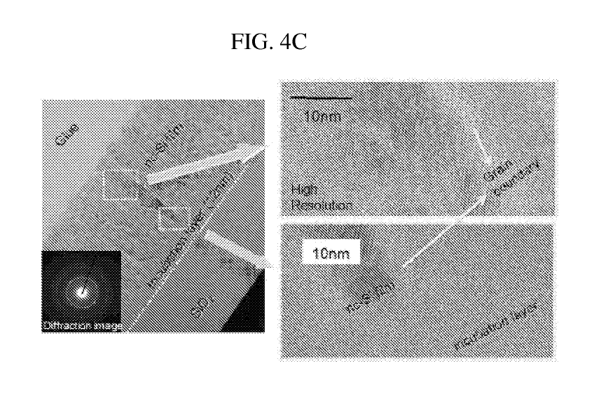

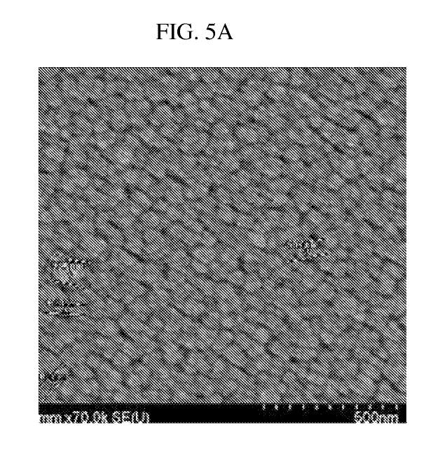

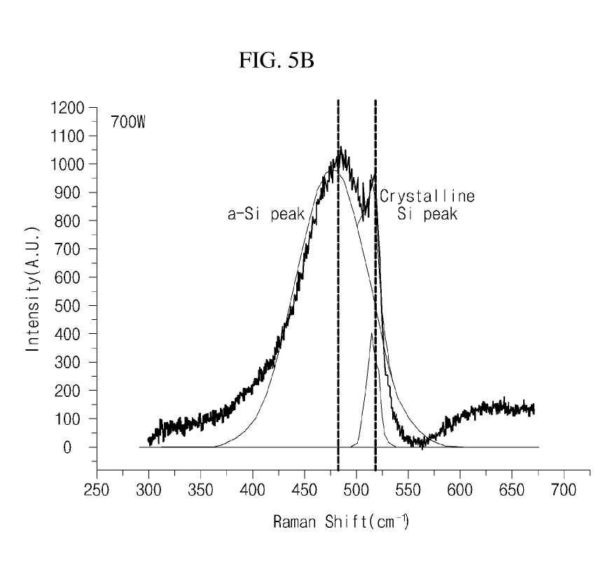

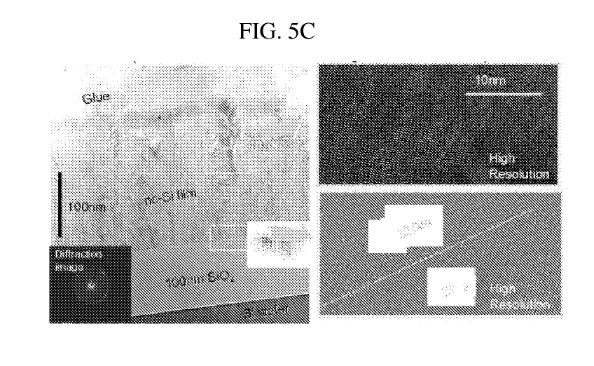

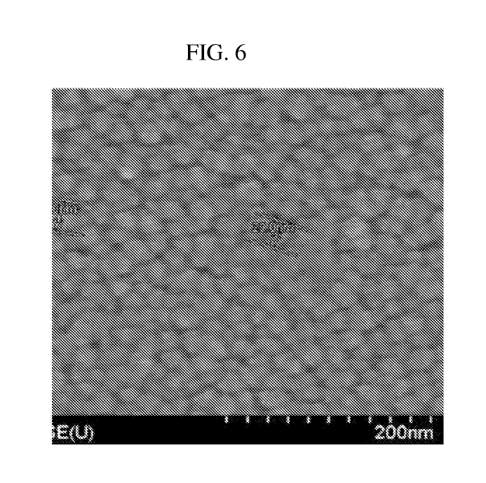

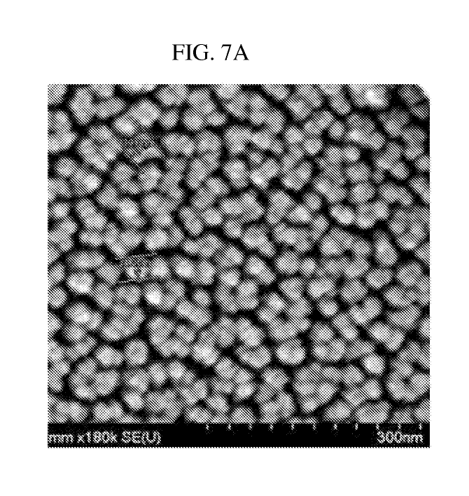

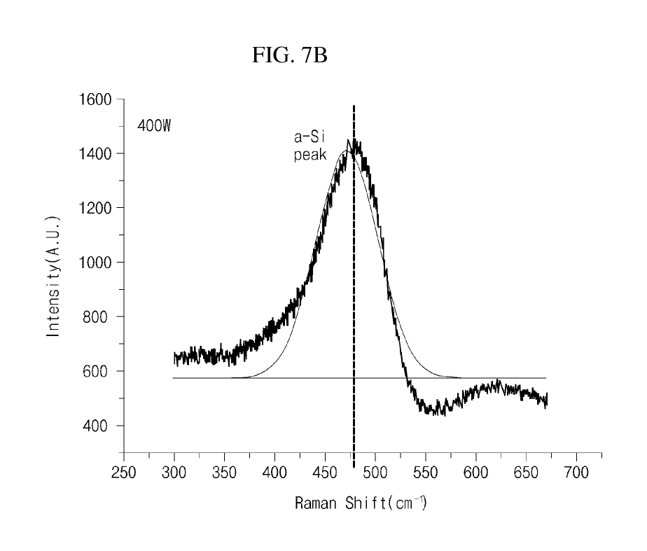

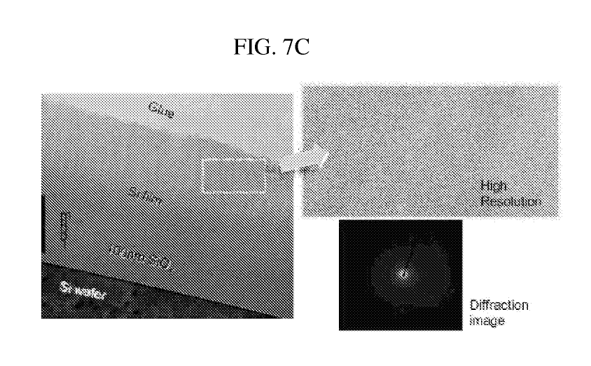

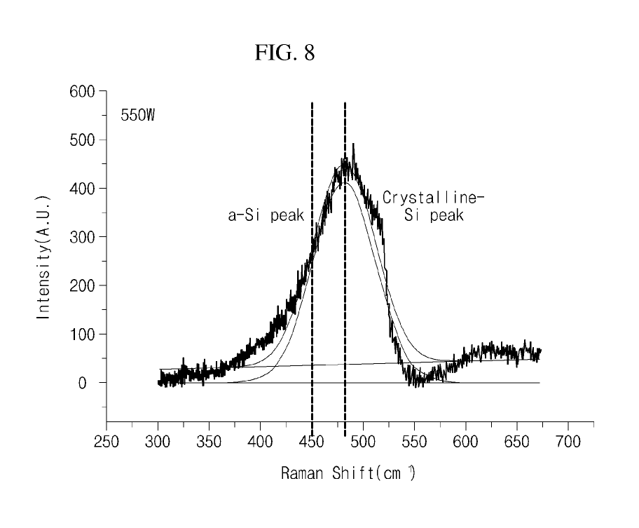

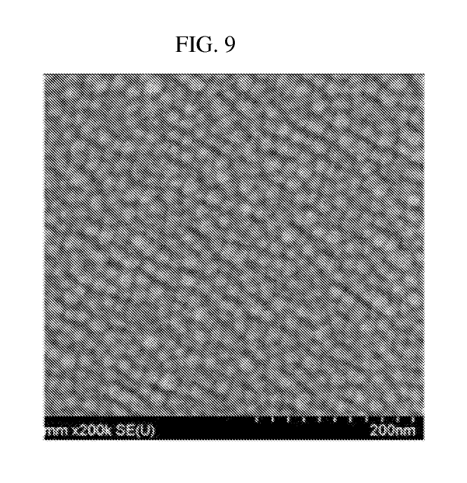

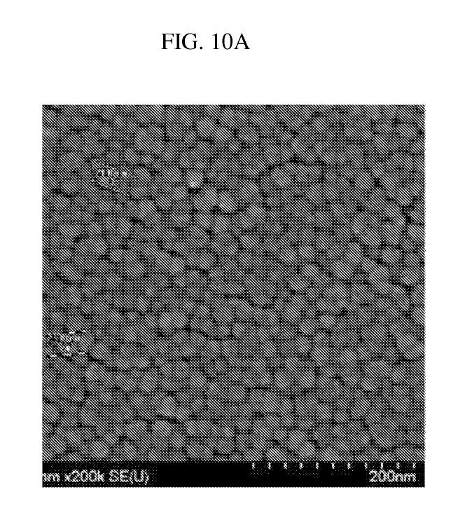

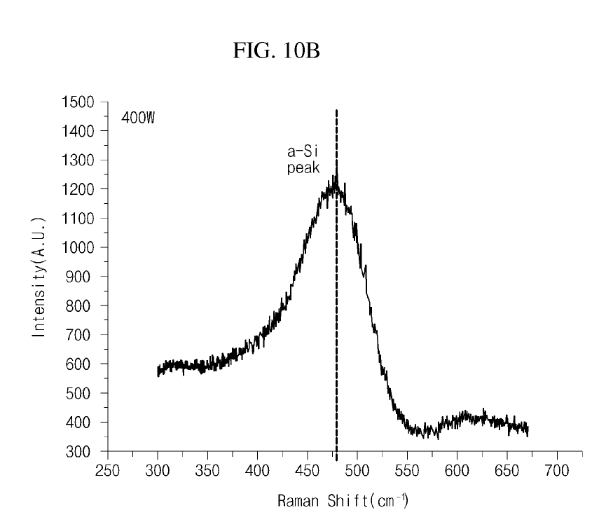

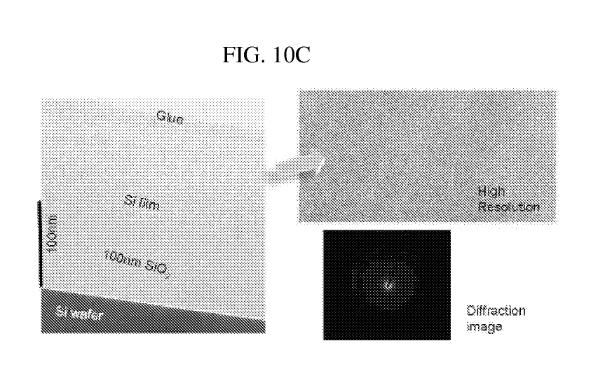

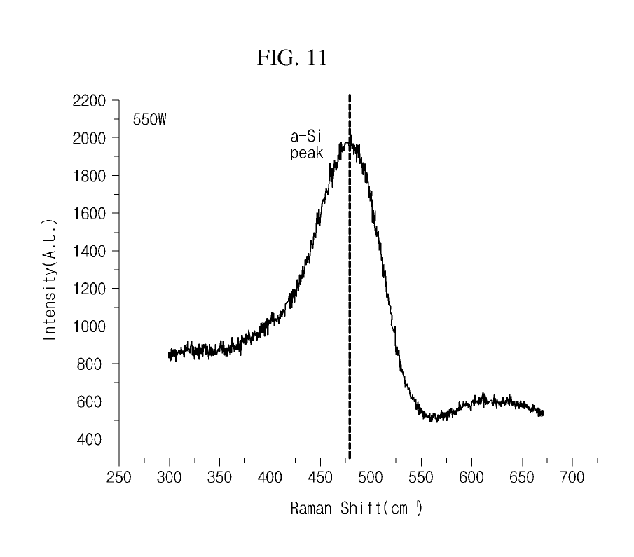

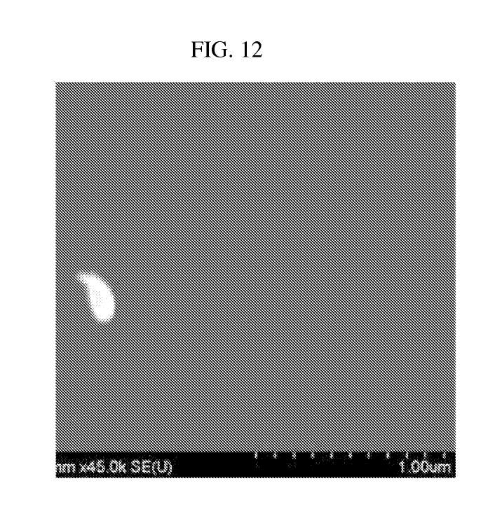

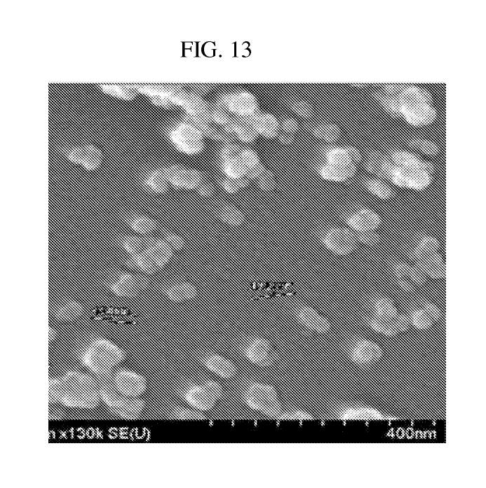

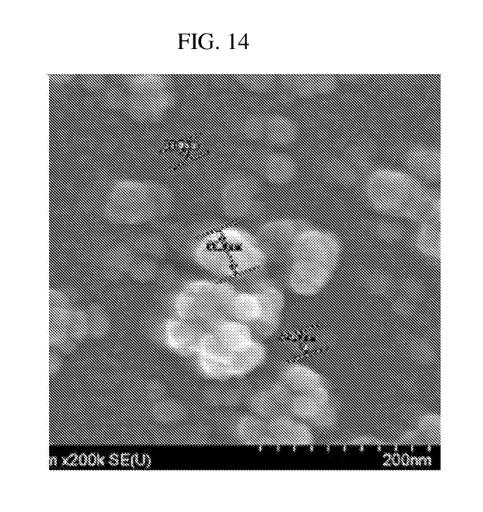

FIGS. 4A to 4C are a scanning electron microscope (SEM) photograph, a Raman spectroscopic analysis and a transmission electron microscope (TEM) photograph of a silicon film deposited by Example 2; FIGS. 5A to 5C are an SEM photograph, a Raman spectroscopic analysis and a TEM photograph of a silicon film deposited by Example 3; FIG. 6 is an SEM photograph of a silicon film deposited by Comparative Example 2; FIG. 7A to 7C are an SEM photograph, a Raman shift spectral analysis and a TEM photograph of a silicon film deposited by Comparative Example 3; FIG. 8 is a graph illustrating a Raman shift spectral analysis of a silicon film deposited by Comparative Example 4; FIG. 9 is an SEM photograph of a silicon film deposited by Comparative Example 5; FIGS. 10A to 10C are an SEM photograph, a Raman shift spectral analysis and a TEM photograph of a silicon film deposited by Comparative Example 6; FIG. 11 is a graph illustrating a Raman shift spectral analysis of a silicon film deposited by Comparative Example 7; FIG. 12 is an SEM photograph of a silicon film deposited by Comparative Example 8; FIG. 13 is an SEM photograph of a silicon film deposited by Comparative Example 9; and FIG. 14 is an SEM photograph of a silicon film deposited by Comparative Example 10.

### EXAMPLES 2-3 AND COMPARATIVE EXAMPLES 2-10

In Examples 2-3 and Comparative Examples 2-10, 1000 Å thick quartz and SiO substrates were not subjected to pre-annealing treatment, and ICP-CVD was continuously performed for 800 seconds to deposit silicon films on the substrates under processing conditions of reactant gas (He:SiH₄) composition ratio He:SiH₄=40:3 [sccm], chamber pressure and ICP power as listed in Table 1.

TABLE 1

| | Chamber deposition | ICP power |
|---|---|---|
| | pressure (mT) | intensity (W) |
| Example 2 | 50 | 700 |
| Example 3 | 200 | 700 |
| Comparative Example 2 | 50 | 100 |
| Comparative Example 3 | 50 | 400 |
| Comparative Example 4 | 50 | 550 |
| Comparative Example 5 | 200 | 100 |
| Comparative Example 6 | 200 | 400 |
| Comparative Example 7 | 200 | 550 |
| Comparative Example 8 | 500 | 100 |
| Comparative Example 9 | 500 | 400 |
| Comparative Example 10 | 500 | 700 |

Referring to FIG. 4A, as confirmed from the SEM photograph, the silicon film deposited in Example 2 had a clean steric grain structure. Referring to FIG. 4B, as confirmed from the Raman spectral analysis, the silicon film deposited in Example 2 demonstrated a crystalline Si peak and the crystallinity degree of approximately 27%. Referring to FIG. 4C, as confirmed from the TEM photograph, the nanocrystalline silicon (nc-Si) film deposited in Example 2 included vertically oriented columnar crystals, a 12 nm thick incubation layer was formed under the nanocrystalline silicon film. In addition, as evident from the high resolution TEM photograph shown in the upper right side of FIG. 4C, a clean Si lattice pattern was observed from grains. As evident from the diffraction image shown in the lower left side of FIG. 4C, the nanocrystalline silicon (nc-Si) film was deposited and a clean concentric pattern was observed from the nc-Si film. The centrally positioned hollow pattern is presumably attributable to existence of an amorphous incubation layer.

Referring to FIG. 5A, as confirmed from the SEM photograph, the silicon film deposited in Example 3 had a clean steric grain structure. It is also confirmed that the silicon film deposited in Example 3 has a cluster structure in which small grains gather to form a 100 nm cluster. Referring to FIG. 5B, as confirmed from the Raman spectral analysis, the silicon film deposited in Example 3 demonstrated a crystalline Si peak and the crystallinity degree of approximately 8%. Referring to FIG. 5C, as confirmed from the TEM photograph, the nanocrystalline silicon (nc-Si) film deposited in Example 3 included vertically oriented columnar crystals. In addition, as evident from the high resolution TEM photograph shown in the upper right side of FIG. 5C, a clean Si lattice pattern was observed from grains. As evident from the diffraction image shown in the lower left side of FIG. 5C, the nanocrystalline silicon (nc-Si) film was deposited and a clean concentric pattern was observed from the nc-Si film.

Referring to FIG. 6, as confirmed from the SEM photograph, the silicon film deposited in Comparative Example 2 had constant pattern structures without an unclear grain boundary, suggesting that amorphous silicon (a-Si) film was deposited due to insufficient ICP power intensity, that is, 100 W.

Referring to FIG. 7A, as confirmed from the SEM photograph, the silicon film deposited in Comparative Example 3 had constant pattern structures with amorphous components existing between the constant pattern structures. In order to definitely determine whether the silicon film was crystallized or not, the silicon film was analyzed by Raman spectroscopy. Referring to FIG. 7B, as confirmed from the Raman spectral analysis, the silicon film deposited in Comparative Example 3 had only an a-Si peak. That is to say, since the ICP power intensity of 400 W was not sufficiently high, it was confirmed that the amorphous silicon film having a crystallinity degree of 0% was deposited. In addition, referring to FIG. 7C, as confirmed from the TEM photograph, the silicon film deposited in Comparative Example 3 had no crystalline structure, suggesting that the constant pattern structures were amorphous clusters, as confirmed from the SEM photograph.

Referring to FIG. 8, as confirmed from the Raman spectral analysis, the silicon film deposited in Comparative Example 4 had only an a-Si peak. That is to say, since the ICP power intensity of 550 W was not sufficiently high, it was confirmed that the amorphous silicon film having a crystallinity degree of 0% was deposited in Comparative Example 4.

Referring to FIG. 9, as confirmed from the SEM photograph, the silicon film deposited in Comparative Example 5 had constant pattern structures without an unclear grain boundary. In addition, the silicon film deposited in Comparative Example 5 appeared to have smaller sizes than the silicon film deposited in Comparative Example 2, and have low-density clusters, suggesting that the amorphous silicon (a-Si) film having a crystallinity degree of 0% was deposited due to insufficient ICP power intensity, that is, 100 W.

Referring to FIG. 10A, as confirmed from the SEM photograph, the silicon film deposited in Comparative Example 6 had constant pattern structures with amorphous components existing between the constant pattern structures. In order to definitely determine whether the silicon film was crystallized or not, the silicon film was analyzed by Raman spectroscopy. Referring to FIG. 10B, as confirmed from the Raman spectral analysis, the silicon film deposited in Comparative Example 6 had only an a-Si peak. That is to say, since the ICP power intensity of 400 W was not sufficiently high, it was confirmed that the amorphous silicon film having a crystallinity degree of 0% was deposited. In addition, referring to FIG. 10C, as confirmed from the TEM photograph, the silicon film deposited in Comparative Example 6 had no crystalline structure. In addition, as evident from the high resolution TEM photograph shown in the upper right side of FIG. 10C, a clean Si lattice pattern was observed from grains. As evident from the diffraction image shown in the lower right side of FIG. 10C, no concentric pattern is observed, as is typical to an a-Si film, suggesting that the constant pattern structures of the silicon film deposited in Comparative Example 6 were amorphous clusters, as confirmed from the SEM photograph.

Referring to FIG. 11, as confirmed from the Raman spectral analysis, the silicon film deposited in Comparative Example 7 had only an a-Si peak. That is to say, since the ICP power intensity of 550 W was not sufficiently high, it was confirmed that the amorphous silicon film having a crystallinity degree of 0% was deposited.

Referring to FIG. 12, as confirmed from the SEM photograph, the silicon film deposited in Comparative Example 8 had no constant pattern grains. That is to say, since the ICP power intensity of 100 W was not sufficiently high and the chamber deposition pressure of 500 mT caused frequent collisions of activated ions and radicals, the silicon film deposited in Comparative Example 8 was not crystalline.

Referring to FIG. 13, as confirmed from the SEM photograph, the silicon film deposited in Comparative Example 9 had a few constant pattern grains. That is to say, since the ICP power intensity of 400 W was not sufficiently high and the chamber deposition pressure of 500 mT caused frequent collisions of activated ions and radicals, the silicon film deposited in Comparative Example 9 was not crystalline.

Referring to FIG. 14, as confirmed from the SEM photograph, the silicon film deposited in Comparative Example 10 had a few constant pattern grains. That is to say, since the chamber deposition pressure of 500 mT caused frequent collisions of activated ions and radicals, the silicon film deposited in Comparative Example 10 was not crystalline.

Hereinafter, degrees of crystallinity of nanocrystalline silicon films with plasma treatment performed thereon according to the present invention will be described based on specific examples.

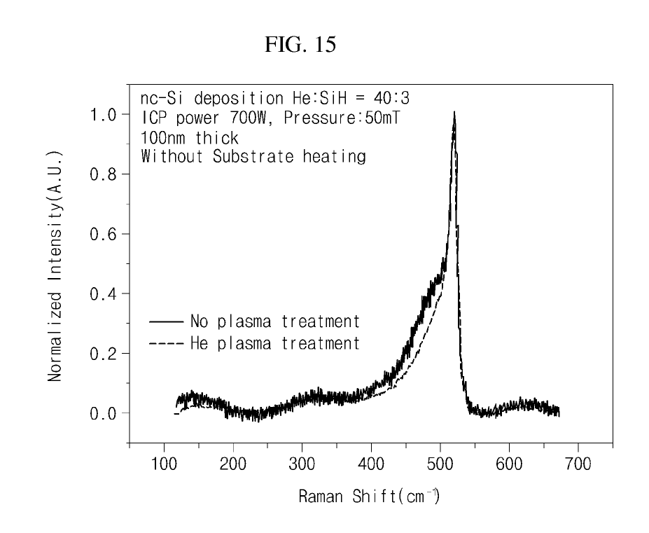

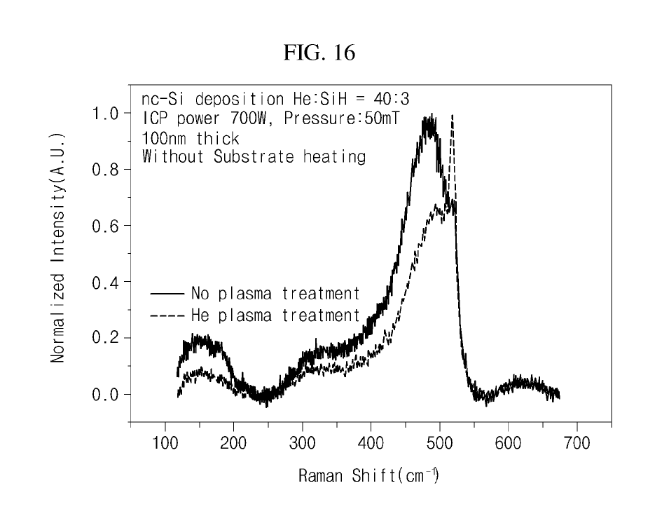

FIG. 15 is a graph illustrating a Raman shift spectral analysis of silicon films deposited by Examples 1 and 3; and FIG. 16 is a graph illustrating a Raman shift spectral analysis of silicon films deposited by Examples 2 and 4.

### EXAMPLES 3-4

1000 Å thick quartz and SiO substrates were prepared and subjected to He plasma treatment until the quartz and SiO substrates reached 150° C., and ICP-CVD was continuously performed for 800 seconds to deposit nanocrystalline silicon (nc-Si) films on the substrates under process conditions including RF power of 700 W, reactant gas (He:SiH₄) composition ratio He:SiH₄=40:3 [sccm], and chamber pressure of 50 mT (Example 3) and 200 mT (Example 4).

In Example 3, the nc-Si film was deposited under the same conditions as in Example 1, except that He plasma treatment was further performed. Referring to FIG. 15, the graph indicated by thick solid line illustrates Raman spectral analysis of the nc-Si film of Example 1, and the graph indicated by thin dotted line illustrates Raman spectral analysis of the nc-Si film of Example 3. The Raman spectral analyses showed that the nc-Si film of Example 3 had a crystallinity degree of 39.3%, which is improved compared to the nc-Si film of Example 1 having a crystallinity degree of 27%. This is because generation of an incubation layer was suppressed at an initial stage of depositing the silicon film due to sufficiently high heat energy supplied to the substrates due to He plasma treatment.

In Example 4, the nc-Si film was deposited under the same conditions as in Example 2, except that He plasma treatment was further performed. Referring to FIG. 16, the graph indicated by thick solid line illustrates Raman spectral analysis of the nc-Si film of Example 2, and the graph indicated by thin dotted line illustrates Raman spectral analysis of the nc-Si film of Example 4. The Raman spectral analyses showed that the nc-Si film of Example 4 had a crystallinity degree of 21%, which is improved compared to the nc-Si film of Example 2 having a crystallinity degree of 8%. This is because generation of an incubation layer was suppressed at an initial stage of depositing the silicon film due to sufficiently high heat energy supplied to the substrates due to He plasma treatment.

The drawings and the forgoing description gave examples of the present invention. The scope of the present invention, however, is by no means limited by these specific examples. Numerous variations, whether explicitly given in the specification or not, such as differences in structure, dimension, and use of material, are possible. The scope of the invention is at least as broad as given by the following claims.

What is claimed is:

1. A method for forming a nanocrystalline silicon film, the method comprising:
performing plasma treatment on a substrate; and
forming a nanocrystalline silicon film by depositing the nanocrystalline silicon film on the substrate.

2. The method of claim 1, wherein the forming of the nanocrystalline silicon film comprises depositing the nanocrystalline silicon film by inductively coupled plasma-chemical vapor deposition (ICP-CVD).

3. The method of claim 1, wherein the plasma treatment is selected from the group consisting of helium (He) plasma treatment, hydrogen (H₂) plasma treatment, and mixture thereof.

4. The method of claim 2, wherein the plasma treatment is selected from the group consisting of helium (He) plasma treatment, hydrogen (H₂) plasma treatment, and mixture thereof.

5. The method of claim 1, wherein the performing of the plasma treatment performs the plasma treatment until the substrate surface reaches a temperature in a range of 80° C. to 150° C.

6. The method of claim 2, wherein the performing of the plasma treatment performs the plasma treatment until the substrate surface reaches a temperature in a range of 80° C. to 150° C.

7. The method of claim 3, wherein the performing of the plasma treatment performs the plasma treatment until the substrate surface reaches a temperature in a range of 80° C. to 150° C.

8. The method of claim 4, wherein the performing of the plasma treatment performs the plasma treatment until the substrate surface reaches a temperature in a range of 80° C. to 150° C.

9. The method of claim 2, wherein the ICP-CVD is performed using a reactant gas wherein the reactant gas is selected from the group consisting of SiH4, diluted helium (He), and mixture thereof.

10. The method of claim 4, wherein the ICP-CVD is performed using a reactant gas wherein the reactant gas is selected from the group consisting of SiH4, diluted helium (He), and mixture thereof.

11. The method of claim 6, wherein the ICP-CVD is performed using a reactant gas wherein the reactant gas is selected from the group consisting of SiH4, diluted helium (He), and mixture thereof.

12. The method of claim 2, wherein in the forming of the nanocrystalline silicon film, a chamber deposition pressure ranges from 30 mT to 250 mT.

13. The method of claim 4, wherein in the forming of the nanocrystalline silicon film, a chamber deposition pressure ranges from 30 mT to 250 mT.

14. The method of claim 6, wherein in the forming of the nanocrystalline silicon film, a chamber deposition pressure is 50 mT.

15. The method of claim 8, wherein in the forming of the nanocrystalline silicon film, a chamber deposition pressure is 50 mT.

16. The method of claim 2, wherein ICP power intensity of the ICP-CVD ranges from 600 W to 800 W.

17. The method of claim 4, wherein ICP power intensity of the ICP-CVD ranges from 600 W to 800 W.

18. The method of claim 6, wherein ICP power intensity of the ICP-CVD is 700 W.

19. The method of claim 8, wherein ICP power intensity of the ICP-CVD is 700 W.

20. The method of claim 15, wherein ICP power intensity of the ICP-CVD is 700 W.
